(19) United States
(12) Patent Application Publication
(10) Pub. No.: US 2012/0120612 A1
(43) Pub. Date: May 17, 2012

(54) ROUTING DEVICE FOR ELECTRONIC DEVICE AND METHOD OF ASSEMBLING ELECTRONIC DEVICE

(76) Inventor: MICHAEL TRAN, MISSISSAUGA (CA)

(21) Appl. No.: 12/944,167

(22) Filed: Nov. 11, 2010

(51) Int. Cl. H05K 7/00; G02B 6/44; H01R 43/00; H05K 5/00

(52) U.S. Cl. 361/730; 174/520; 361/807; 385/101; 29/857

(57) ABSTRACT

A device for routing cables within a housing of an electronic device, an electronic device incorporating said routing device and a method of assembling an electronic device with said routing device are disclosed. The device includes a length of tube with a specific shape to route the cables in the tube within a housing of the electronic device. The specific shape includes bends to route cables to provide space between the cables and electronic components within the housing to reduce electromagnetic interference between the cables and electronic components within the housing. The electronic device has a modular assembly with interchangeable endcap modules that can be changed according to communication requirements. The cables connect antennas or other electronic components in the endcap module with electronic components within the device housing, such as a communications module. The tube can also be connected to the endcap in a hinged manner. The endcap module can be assembled with the portable electronic device by inserting the tubing containing the cable attached to the endcap into the housing and fastening the endcap to the housing to position the tube within the housing to route the cables to reduce electromagnetic interference.

### FIELD

The present invention relates generally to a routing device and method of assembling an electronic device incorporating said routing device.

### INTRODUCTION

Current portable or handheld electronic devices contain a number of electronic components to support device displays, user interfaces, communication interfaces and power requirements. Many of these components either generate electromagnetic interference or are susceptible to the effects of electromagnetic interference. Low power signals, including received radio frequency signals, are especially susceptible to electromagnetic interference. A radio transmitter can generate electromagnetic interference that can affect other components of the electronic device. The design of electronic devices requires careful layout of the electronic components and their interconnects in order to avoid deleterious effects of electromagnetic radiation. Reducing the effects of electromagnetic radiation is a design concern with portable electronic devices where the trend is towards lower power designs with reduced battery requirements.

Modular electronic devices can allow an end-user to reconfigure the device by installing or swapping modules on the electronic device. Modular electronic devices also provide a more economical method of assembly of different device configurations through assembly with the appropriate modules. Each module can include different components and connect to the device electronics through different interconnects. Each component or interconnect in a module can have their own susceptibility to electromagnetic interference or emit electromagnetic radiation that can affect other components in the device. Therefore, each module can have its own design requirement for the layout of the components and interconnects to avoid the effects of electromagnetic interference.

A modular portable electronic device or handheld electronic device can be reconfigured to use different communication networks or a scanning device by swapping an endcap module of the device. Each endcap module can contain electronic components or an antenna and have an attached cable that is routed and connected within the housing of the device. Different endcap modules can have different requirements for where the attached cable can be routed within the electronic device. For an end-user, or even an assembly worker, correctly routing the attached cable according to the design requirements can be a difficult task that is prone to error. Failure to properly route the attached cable within the device can result in suboptimal performance of the electronic device.

Assembling a modular device has a number of challenges. The housing of the device can have a number of blind spots where the assembler's view is obstructed by components or portions of the housing itself. Blind spots can obscure the path of the attached cable within the housing making it difficult to ensure the cable is routed away from any areas sensitive to electromagnetic interference. Attached cables can also have a minimum bend radius that must be maintained to ensure the integrity of cable and any signals transmitted through the cable. Cables from the endcap module are also prone to being pinched or crimped within the device or between the device housing and the housing of the endcap module. The attached cables should also have enough slack to allow the module to be assembled, yet not too much slack in the cable such that the cable risks being damaged.

### SUMMARY OF THE INVENTION

According to a first aspect, an electronic device is provided comprising a housing containing electronic components for operation of the electronic device, including a ommunications module; an endcap module attached to the housing; a length of tube having a specific shape to route the feed line to provide space between the feed line and electronic components to reduce electromagnetic interference between the feed line and the electronic components. In a further aspect, the endcap module is removable. In a still further aspect, the length of tube is hingedly attached to the endcap module. In a further aspect, an end of the length of tube branches to separately route antenna cables whose connectors or the branch are color coded to correspond to the color of the connector of the corresponding communications module.

According to a second aspect, a method is provided for assembling an endcap module to an electronic device housing comprising the steps of inserting an feed line provided within a tube having bends to route the feed line to provide space between the feed line and electronic components within the housing to reduce electromagnetic interference between the feed line and the electronic components, an end of the feed line connected to the endcap module; attaching a connector from an opposite end of the feed line provided within the tube to a communications module within the device housing; and fastening the endcap module to the housing to secure the tube within the housing to route the feed line within the housing to reduce electromagnetic interference to an acceptable level. In a further aspect, the method comprises selecting the endcap module in response to a communication requirement.

According to another aspect, a device is provided for routing cables within a housing of an electronic device, the device comprising a length of tube having a specific shape to route a feed line provided therein within the housing of the electronic device, wherein the specific shape includes bends to route the one or more cables. In a further aspect, the cables are antenna cables and the specific shape routes the antenna cable to provide space between the antenna cable and electronic components to reduce electromagnetic interference between the antenna cable and the electronic components. In a still further aspect, the antenna cables connect the antenna to a communications module of the electronic device.

### BRIEF DESCRIPTION OF THE DRAWINGS

For a better understanding of the various embodiments described herein and to show more clearly how they can be carried into effect, reference will now be made, by way of example only, to the accompanying drawings which show at least one exemplary embodiment, and in which:

FIG. 1 is a block diagram and side view of a housing of a handheld electronic device;

FIG. 2 is a perspective view of the handheld electronic device of FIG. 1;

FIG. 3 is cross sectional view of a further embodiment of the housing of the device of FIG. 1;

FIG. 4 is a top sectional view of a further embodiment of the device of FIG. 1;

FIG. 5 is a top sectional view of a further embodiment of the device of FIG. 1 showing a branching tube;

FIG. 6 is a side sectional view of a further embodiment of the device of FIG. 1 showing an endcap module attachment to the device housing; and

FIG. 7 is a flowchart diagram showing an example assembly method.

### DESCRIPTION OF VARIOUS EMBODIMENTS

It will be appreciated that for simplicity and clarity of illustration, where considered appropriate, numerous specific details are set forth in order to provide a thorough understanding of the exemplary embodiments described herein. However, it will be understood by those of ordinary skill in the art that the embodiments described herein can be practiced without these specific details. In other instances, well-known methods, procedures and components have not been described in detail so as not to obscure the embodiments described herein. Furthermore, this description is not to be considered as limiting the scope of the embodiments described herein in any way, but rather as merely describing the implementations of various embodiments described herein.

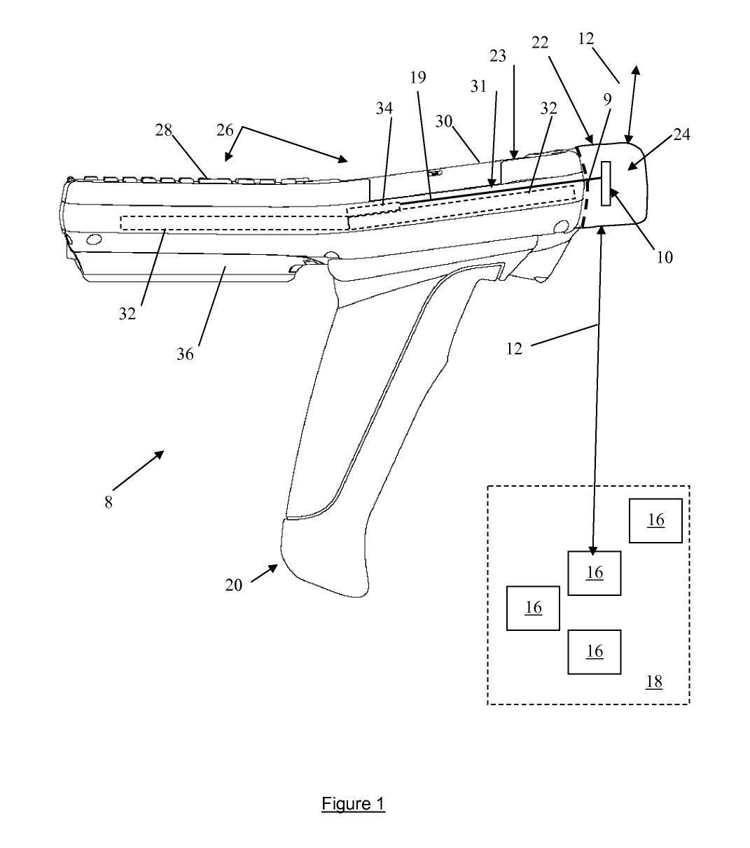

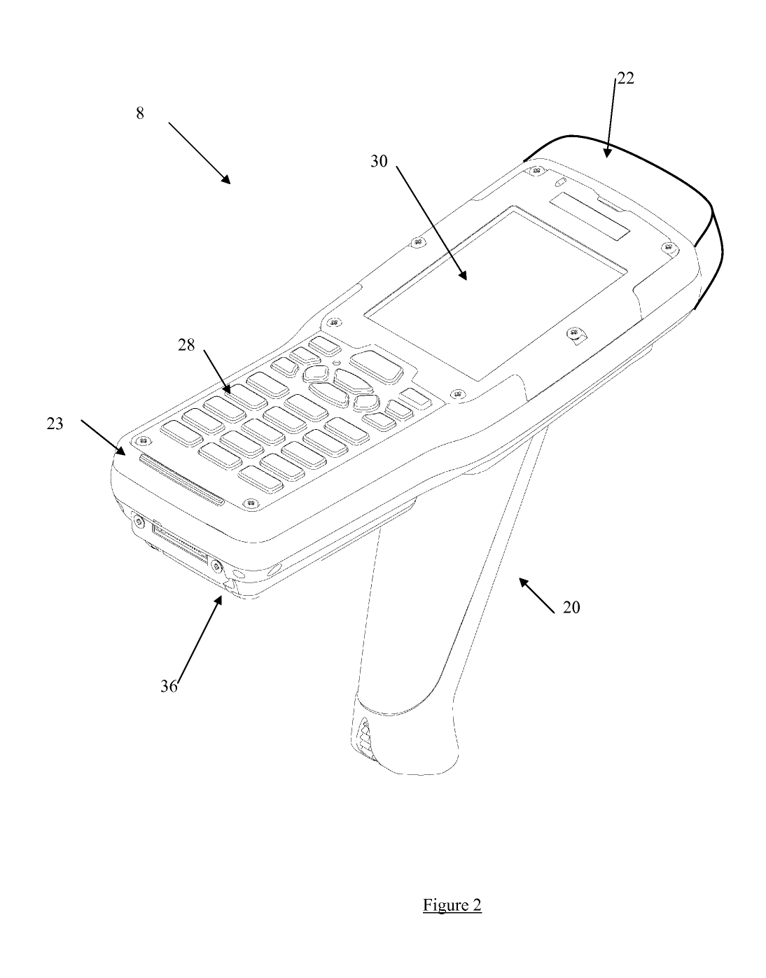

Referring to FIGS. 1 and 2, shown is a portable handheld electronic device 8 which includes an antenna 10 (or scanner device 10). Antenna 10 can receive and/or transmit electromagnetic radiation 12. Antenna 10 can be used for data capture functions, such as, for example, reading and encoding RFID tags. Antenna 10 can also be used for communication functions where antenna 10 is an antenna type used in wireless communication systems and/or networks such as WAN, WiFi, and/or Bluetooth, GPS communication technologies. Electromagnetic radiation 12 can be used for asset tracking/management in connection with antenna 10, for example in wireless communication with tracking objects 16 (e.g. RFID tags) present in one or more logistics environments 18. It is recognized that tracking objects 16 can be attached to products that are being transported from one location to another in logistics environment 18. Examples of an logistics environment 18 can include, but are not limited to: front store retail and/or warehousing for mobile stock checking, price checking, and merchandising; and utilities for meter reading, surveying, parking enforcement, and asset tracking. Embodiments incorporating scanner device 10 can be used to read bar code type information, such as a laser bar code reader or an imager. It is also recognized that electronic device 8 can be embodied as any generic mobile device such as, for example, a mobile communication device, the handheld as described, a portable electronic device, or a body-worn personal communication device.

Electronic device 8 has housing 23 having a first interior 31 for housing (completely or at least partially within) a plurality of electronic components and an endcap module 22 (coupled to housing 23) for housing antenna 10. Electronic components can be contained on one or more printed circuit boards 32. It is recognized that antenna 10 can be completely enclosed in an interior 24 of endcap module 22 as shown in FIGS. 1 and 2, or can be partially enclosed in interior 24. Electronic device 8 can be reconfigured to use different data capture functions or communication networks by changing endcap module 22 to another endcap module that contains the appropriate antennas or scanner devices for the communications or scanning requirements. In some embodiments, endcap module 22 can include an antenna 10 or scanner device 10 along with electronics, that can include an electronics module used to recover the data signal that is then communicated to electronic device 8.

Electronic device 8 can also include an electromagnetic shield 9 positioned between first interior 31 and second interior 24 for inhibiting electromagnetic interference (EMI) between antenna 10 and the electrical components within first interior 31. Electromagnetic shield 9 is configured for facilitating electromagnetic isolation for antenna 10 from adjacent interfering components.

Electronic device 8 can have an optional handle 20, connected via a releasable, securable connection, to housing 23. It is also recognized that handle 20 can be fixedly attached (e.g. not releasable) to housing 23 by fastening means. Further, it is recognized that handle 20 can be formed (e.g. molded) as integral to at least a portion of housing 23.

Electronic device 8 can also include: a user interface 26, including a keyboard 28 and a display 30 (e.g. touch screen), one or more onboard processors (not shown), and a communications module 34 for communicating via feed line 19 to endcap module 22. Electronic device 8 can also have an onboard power source, such as battery 36, for helping to satisfy power requirements of the onboard processor(s), user interface 26, and communications module 34. It is recognized that feed line 19 can be positioned between interiors 24 and 31 through a hole or slot in electromagnetic shield 9.

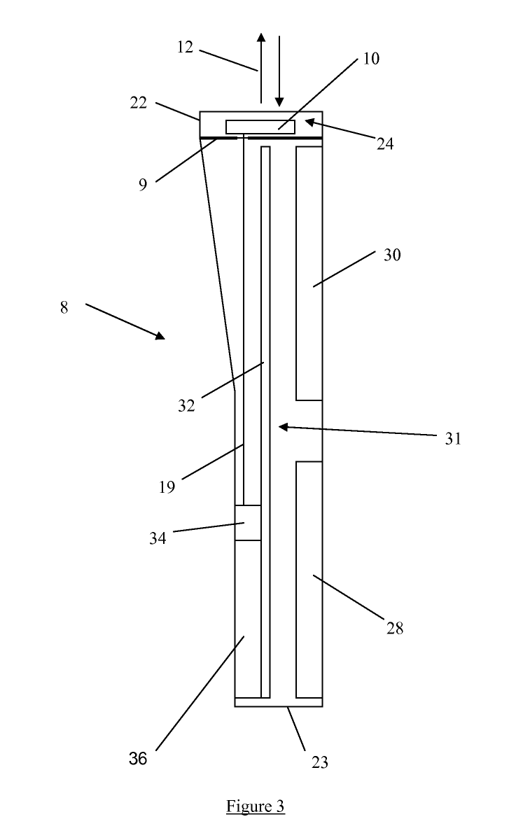

Referring now to FIG. 3, antenna 10 can have a physical form factor that allows it to be embedded within endcap module 22 (i.e. into interior 24 of endcap module 22). Electronic device 8 can also include a battery 36 for powering electronic components, such as communications module 34. Feed line 19 couples antenna 10 within endcap module 22 to communications module 34. Communications module 34 can be a transmitter for transmitting, a receiver for receiving or combined as a transceiver for both transmission and reception of electromagnetic radiation 12. Endcap module 22 can be positioned on either the top or bottom end of housing 23 of electronic device 8 adjacent to display 30 and/or keypad 28. It is also recognized that endcap module 22 can be positioned on a backside of housing 23 opposite display 30 and/or keypad 28, on the frontside of housing 23, and on the sides of housing 23. Endcap module 22 may be either fixedly attached or releasably attached to housing 23.

It is recognized that antenna 10 can be configured to function as a WAN, WIFI and/or Bluetooth communication technologies antenna 10 (e.g. non-directional based antennas), and/or as a directional antenna 10 (e.g. RFID scanner). Although a singular antenna is described above, multiple antennas can be configured and housed within endcap module 22 and coupled via one or more respective feed lines 19 to one or more respective communications modules 34. Also, one or more transmitting and one or more receiving antennas can be configured and installed within endcap module 22.

Referring again to FIG. 1, antenna 10 can be referred to as a transducer designed to transmit and/or receive electromagnetic radiation 12 from the surrounding environment. Accordingly, antenna 10 converts electromagnetic radiation 12 into electrical currents (e.g. receive operation) and convert electrical currents into electromagnetic radiation 12 (e.g. transmit operation), such that the electrical current is communicated via feed line 19 coupled between antenna 10 and communications module 34.

Electromagnetic radiation 12 can be detected and/or generated by antenna 10 in a variety of frequency ranges, including the UHF RFID band, dual/multi-band 3G/4G applications such as UMTS, CDMA, WiMAX, and/or WiFi in which there are multiple so-called frequency bands. Accordingly, it is recognized that antenna 10 described herein is not limited to UHF RFID applications and could readily be applied to any radio communication technology using other frequencies (e.g. WAN, WIFI, Bluetooth, GPS and/or other). It is recognized that antenna 10 operates as radiating or receiving surface for electromagnetic radiation 12.

As shown in FIG. 1, feed line 19 in a radio transmission, reception or transceiver system can be an antenna cable that carries the RF signal to and/or from the antenna 10. Feed line 19 carries the RF energy for transmission and/or as received with respect to antenna 10. There are different types of feed lines 19 in use in wireless antenna 10 systems, including cables that are shielded or unshielded from electromagnetic radiation. Examples of feed lines 19 can include but are not limited to: the coaxial type, the twin-lead, and, at frequencies above 1 GHz, a waveguide. Waveguides can include an optical cable for transmitting light pulses from a transmitter in the endcap module 22 to communications module 34 that can contain an optical receiver, transmitter or transceiver.

Referring again to FIG. 1, the electrical components of electronic device 8 can include components such as but not limited to: a main logic board (MLB) or other printed circuit board(s) 32; communications module 34 including receivers/transmitters/transceivers for use with antenna 10; user interface devices (e.g. keypad 28, display 30), power circuitry for charging/discharging battery 36, and memory devices. For example, the MLB is the main printed circuit board (PCB) 32 that provides the electrical connections by which the other electrical components of electronic device 8 communicate and hosts the processing unit and other subsystems housed in housing 23. Printed circuit board 32 can also contain a chipset which forms an interface between the CPU's front-side bus, main memory, and peripheral buses, non-volatile memory chips (e.g. Flash ROM) containing electronic device 8 firmware and/or BIOS for electronic device 8, a clock generator which produces the system clock signal to synchronize the various components, and/or slots for expansion ports that can be interfaced via the buses supported by the chipset. Communications module 34 is one of the electrical components that is connected to antenna 10 via feed line 19. Communications module 34 is an electronic circuit that receives and/or transmits its input/output from/to antenna 10 via feed line 19, uses electronic filters to separate any wanted radio signals or noise from electromagnetic radiation 12 received by antenna 10, amplifies the received signals to a level suitable for further processing or transmission, and converts the signal, through modulation/demodulation and encoding/decoding the signal, into a suitable form.

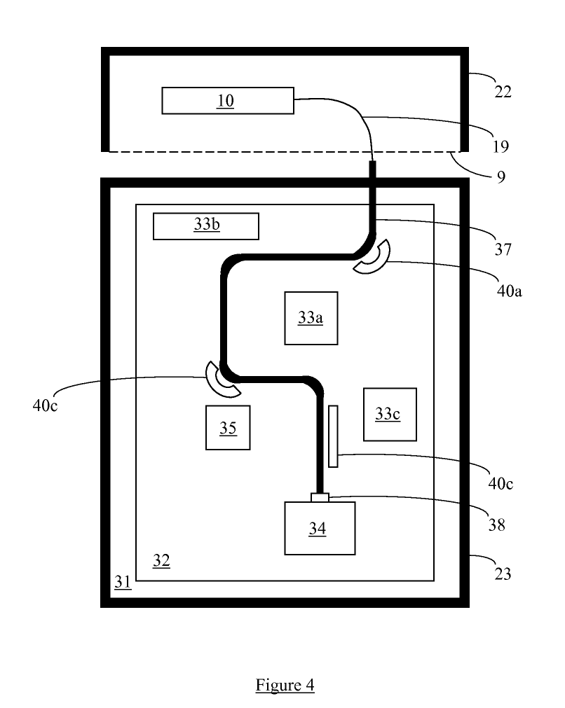

Referring to FIG. 4, shown is a top sectional view of electronic device 8 showing electronic components 33a-c mounted on printed circuit board 32. Electronic components, some of which are shown as electronic components 33a-c mounted on printed circuit board 32, can emit electromagnetic radiation that can interfere with signal information propagated by feed line 19. Also, the operation of electronic components 33a-c can be affected by any electromagnetic radiation emitted by feed line 19 or antenna 10. The purpose of electromagnetic shield 9 is to inhibit (or otherwise reduce) the propagation of the electromagnetic radiation between housing 23 and endcap module 22.

Electromagnetic interference (or EMI, also called radio frequency interference) is a disturbance that can affect the operation of an electrical circuit (e.g. any of the electrical components 33a-c or antenna 10) due to either electromagnetic conduction or electromagnetic radiation emitted from an external source, such as either a source outside housing 23 or endcap module 22, or from feed line 19. The disturbance can interrupt, obstruct, or otherwise degrade or limit the effective performance of the circuit. The source can be any object, artificial or natural, that carries rapidly changing electrical currents, such as an electrical circuit of electrical components 33a-c or the radiative elements of antenna 10. Electrical components 33a-c can be either components that are sensitive to electromagnetic interference, such as, for example, circuitry that process low level electronic signals, or electrical components 33a-c can also be components that radiate electromagnetic interference, such as, for example, power supply circuitry that can include charging/discharging capacitive elements.

In some embodiments, communications module 34 can comprise a radio transmitter that transmits high power radio signals. The high power radio signals can also be transmitted in high power bursts. These radio signals can cause feed line 19 to emit electromagnetic interference that can affect the operation of electronic components 33a-c. In other embodiments, antenna 10 can receive a low power signal that is transmitted by feed line 19 to communications module 34. If any one of electronic components 33a-c are emitting electromagnetic radiation, the radiation from any one of electronic components 33a-c can obscure the signal carried by feed line 19 resulting in poor performance.

In still other embodiments, feed line 19 can be an optical wave guide having a minimum bend radius. For example, endcap module 22 can contain a scanner device 10 and associated electronic components for processing the captured signal. The associated electronic components can transmit the processed signal using an LED or laser that is connected to feed line 19, in this case an optical cable, that is connected to an optical detector, such as a photodiode, within housing 23. Although optical cables can be immune to electromagnetic interference, the optical cables themselves are fragile and can break or attenuate the signal if the cables are bent beyond the minimum bend radius or are pinched within housing 23.

Antenna 10 within endcap module 22 is connected by feed line 19 that is disposed within tube 37. Tube 37 is a long hollow member, such as a cylindrical tube, that provides the routing path for feed line 19 from endcap module 22 to communications module 34. As will be apparent, tube 37 need not have a cylindrical cross section, and can have other cross sections, such as oval, square or rectangular, and can have varying cross sections along its length (e.g. square along a straight section but circular at bends). Tube 37 is shaped in order to route feed line 19 away from electromagnetically sensitive components, such as electronic components 33a-c. Tube 37 can be constructed from a resilient, semi-rigid plastic that allows tube 37 to have some flexibility during positioning within housing 23 yet still maintains its shape within electronic device 8. Tube 37 does not refer to any shielding, insulation layer or cladding that can be a part of feed line 19.

Tube 37 can also have an inner shield (not shown) on the inside of tube 37 that provides shielding from electromagnetic radiation. The inner shield can be composed of a conductive coating on the inside of tube 37. In other embodiments, the inner shield can be composed of a solid shield, such as a metal tube, or a porous shield, such as a braid. If a porous shield is used then the largest dimension of any gap in the shield can be smaller than the quarter wavelength of the highest frequency to be attenuated by the inner shield. If a solid inner shield is used, tube 37 can be constructed from a metal tube that is formed to the appropriate shape that is then covered with a nonconductive coating on the outside surface of the metal tube to prevent the metal tube from creating any short circuits within housing 23. Tube 37 could be similarly constructed using a braided inner shield that can then be coated with either a rigid insulating material to maintain the shape of the braid or a flexible insulating material to allow tube 37 to bend.

In embodiments incorporating an inner shield, the inner shield can be grounded to provide further resistance to electromagnetic interference. An electrical connection between the inner shield and printed circuit board 32 and/or electrical components in endcap module 22 can be used to ground the inner shield. The electrical connection can be formed by metal tabs at each of the ends of tube 37. The electrical connection to printed circuit board 32 can also be made from the inner shield to connector 38 so that connecting connector 38 to printed circuit board 32 (or any module connected thereto) serves to ground the inner shield. The inner shield can be grounded at both ends or at a single end in order to avoid ground loops.

Tube 37 can also be shaped to avoid objects within housing 23, such as object 35 for example, that pose a barrier to routing feed line 19. Object 35 can include, but is not limited to, objects within housing 23 such as portions of the housing, circuit elements protruding from printed circuit board 32, and hardware to secure printed circuit board 32 within housing 23.

In some embodiments, tube 37 can have a longitudinal slot that allows feed line 19 to placed within tube 37. Tube 37 can slide upon feed line 19 between connector 38 and endcap module 22. Feed line 19 can be longer than tube 37 to provide a service loop at either end of the tubing to allow some play in feed line 19 to allow movement of endcap module 22 and tube 37 during the assembly process.

Tube 37 can also be used to maintain a minimum bend radius of feed line 19, especially in embodiments where feed line 19 is a coaxial cable or an optical cable used to connect the elements of endcap module 22 to a component on printed circuit board 32. A minimum bend radius is the radius below which a coaxial cable or optical cable should not be bent to prevent the cable being damaged or destroyed, or the signal being attenuated. For example, tube 37 can be designed so that any bends in the tube are above the minimum bend radius for any cable disposed therein. Tube 37 can be constructed to have multiple sections having different rigidities so that the section of tube 37 that defines a bend is constructed from a rigid material to maintain the radius of a bend above the cable specification and other portions of tube 37 are constructed of less rigid material. In other embodiments, sections of tube 37 can be constructed from a rigid material but sections that define bends can be connected by flexible joints to other sections of tube 37.

Guides 40a-c can be included within housing 23 in order to assist routing the tube 37 through the interior of housing 23. Guides 40a-c can assist placing tube 37 within electronic device 8, especially in areas of housing that are obstructed from view, also known as blind spots. Guides 40a-c assist in defining routing channels within electronic device 8. Guides 40a-c can facilitate bending tube 37 in embodiments where bends in tube 37 are not pre-formed. Guides 40a-c also ensure that tube 37 and feed line 19 are routed away from electronic components that emit or are susceptible to electromagnetic interference. Since electromagnetic radiation attenuates further from the source of the radiation, routing feed line 19 to increase the distance to electromagnetic components reduces the amount of electromagnetic energy that can be transferred to or from feed line 19. For example, guide 40a is placed above component 33a (with reference to the orientation shown in FIG. 4) to ensure that feed line 19 is routed away from electronic component 33a to reduce the transfer of electromagnetic energy to or from feed line 19.

Guides 40a-c can be elements that are affixed to printed circuit board 32 or protrusions on the inner bottom half of housing 23 that fit against printed circuit board 32. Guides can be either shaped, such as guides 40a-b, or straight such as guide 40c. Guides can also be positioned on each side of tube 37.

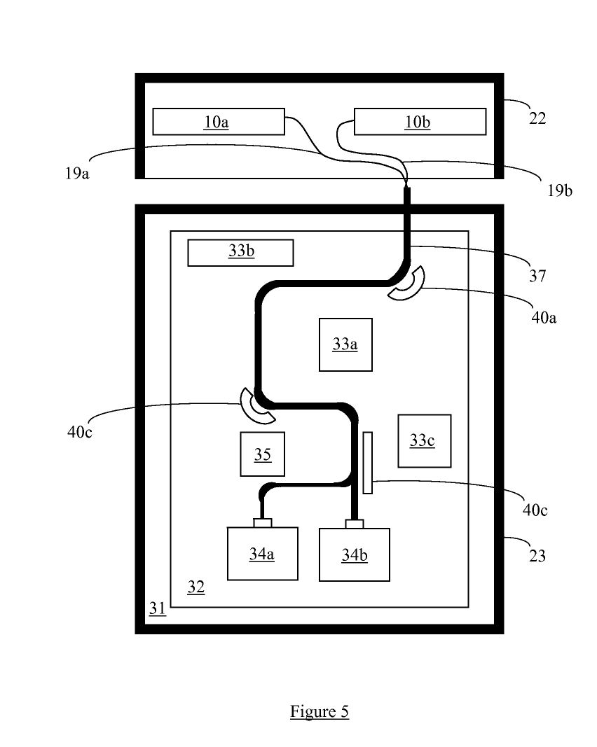

The number of bends and the degrees of the bends of tube 37 shown in FIGS. 4 and 5 are made for illustration purposes. In practical embodiments the bends can be more gradual and can also be greater than 90 degrees. Also, the number of bends in tube 37 or the total degrees of bends can affect how easily the tube can be inserted and routed within electronic device 8. A practical embodiment can incorporate two or three bends with the total degrees of the bends being under 180 degrees. Inclusion of guides 40 can assist with tube insertion and can allow more bends and total degrees of bend.

Referring now to FIG. 5, shown is a top sectional view of electronic device 8 showing tube 37 which includes a branch to route feed lines 19a-b to communications modules 34a-b, respectively, within housing 23. Endcap module 22 can include more than one antenna to provide multiple scanning/communication interfaces that require routing feed lines to different areas of printed circuit board 32. Endcap module 22 includes multiple antennas 10a-b so that electronic device 8 can be configured to use multiple communication networks or scanning techniques. For example, antenna 10a can be configured to transmit/receive Wi-Fi signals and antenna 10b can be configured to interrogate RFID tags. Other embodiments can incorporate any number and combination of antennas/scanners.

Feed lines 19a-b are routed within interior 24 of endcap module 22 by tube 37. Some embodiments can also have a separate tube 37 for each feed line 19a-b to avoid any electromagnetic interference between feed lines 19a-b. In still other embodiments, feed lines 19a-b can be routed from endcap module 22 in separate branches of the same tube 37 that are joined within interior 31 of housing 23. The embodiment shown in FIG. 5 shows tube 37 routing feed lines 19a-b away from electromagnetically sensitive electronic component 33 and around object 35 within housing 23.

Tube 37 branches into branches 37a and 37b in order to route feed lines 19a and 19b to communication modules 34a and 34b respectively. Branches 37a-b can have a smaller cross-section since they can contain fewer feed lines 19 than in tube 37. The cross-section of a branch can gradually taper towards the end of the branch. At the end of each branch, feed lines 19a-b are connected to connectors 38a-b respectively. Connectors 38a-b can form a snap fit into a connector mounted on printed circuit board 32 that is connected to communication modules 34a-b. In some embodiments, connectors 38a-b can be color coded to correspond to the color of the connector mounted on printed circuit board 32 to ensure the correct connection is made to the correct communications module.

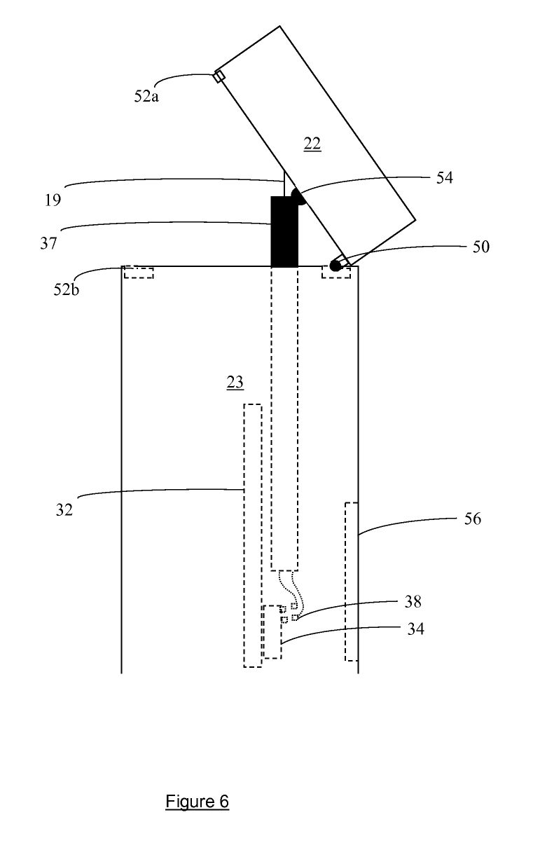

Referring now to FIG. 6, shown is a side sectional view of electronic device 8 with endcap module 22 being attached to housing 23. Due to the modular nature of electronic device 8, operators can wish to reconfigure electronic device 8 through attaching a different endcap module 22 to enable the use of different radio or communication modules according to communication or scanning requirements.

Endcap module 22 is shown having a hinged attachment mechanism 50 that can include a protrusion from endcap module 22 that engages a channel within housing 23. Endcap module 22 can then be hinged downwards and then slid to the right (relative to the orientation shown in FIG. 6) so that attachment 52a on endcap module 22 engages with a mating attachment 52b to secure endcap module 22 to housing 23. Endcap module 22 can be removed by reversing the process (i.e. sliding and then hinging). Other embodiments can employ other attachment mechanisms although those that do not employ additional hardware (such as screws, clamps, etc.) can be preferable to simplify assembly of endcap module 22.

In some embodiments, tube 37 can be hingedly attached to endcap module 22 by tube hinge mechanism 54 to support the motion of hinged attachment mechanism 50. Feed line 19 can also have additional slack or a service loop so that feed line 19 does not overly restrict movement of endcap module 22 relative to housing 23. Tube hinge mechanism 54 can be formed by mating brackets on tube 37 and endcap module 22 and a hinge pin. In other embodiments, tube 37 can be fused or otherwise fixed to endcap module 22 and tube hinge mechanism 54 can be provided by a flexible portion of tube 37, such as but not limited to a concertina/accordion portion of tube 37 capable of flexion.

Housing 23 can also have a service door 56 that can be opened to expose a connector on communication module 34 on printed circuit board 32. Endcap module 22 can be assembled by feeding tube 37 into interior of housing 23 until connector 38 appears in area exposed through service door 56. Communications module 34 is then connected to connector 38 on the end of feed line 19. Next, endcap module 22 can be fastened to housing 23 as described above.

Alternatively, some embodiments can affix tube 37 within housing 23 so that feed line 19 can be inserted into tube 37 when installing endcap module 22. Since it can be difficult to push feed line 19 through tube 37, tube 37 can include a pull line (not shown) that can be used to pull feed line 19 through tube 37. Pull lines can be especially useful if tube 37 has more than 45 degrees of bends or tube 37 includes branches. If tube 37 includes multiple branches, multiple pull lines can be inserted into tube 37 that each have a visual indication for which pull line corresponds with which branch of tube 37. The pull line can be installed prior to affixing tube 37 within housing 23. In some embodiments, feed line 19 can be placed within a ground braid prior to inserting feed line 19 into tube 37.

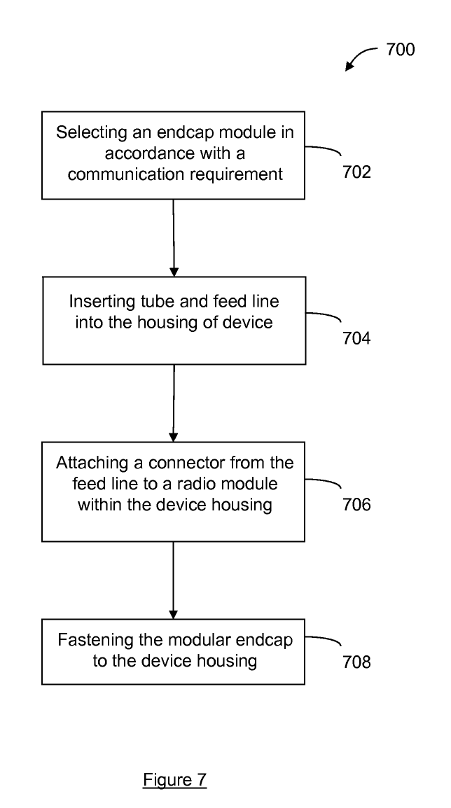

Referring now to FIG. 7, shown is a method 700 of assembling an endcap module 22 containing an antenna 10 to housing 23 of electronic device 8. First in step 702, endcap module 22 is selected in accordance with a communication requirement. Since each endcap module 22 may need to connect to different communication modules, each endcap module 22 can have a distinct routing requirement. The assembly process is simplified since the shape of each tube for each endcap corresponds to the correct routing of feed lines 19 for that endcap module 22. The communication requirement can be related to the type of communication network electronic device 8 is to communicate over. The communication requirement can also relate to type of scanning technology to be used by electronic device 8, such as RFID, laser scanning and/or imaging. The communication requirement can include one or more specified communication networks or scanning technologies. Example communication requirements could include WiFi communications and RFID UHF scanning that result in selecting an endcap module containing components capable of both WiFi and RFID UHF communications.

After endcap module 22 has been selected, feed line 19 attached to endcap module 22 that is within the above-described tube 37 is inserted into housing 23 at step 704. Feed line 19 is inserted into housing 23 so that connector 38 attached to feed line 19 can reach the appropriate communications module 34 of electronic device 8. The shape of tube 37 provides the correct routing channel within housing 23 for feed lines 19 provided therein. The shape of the tube 37 can also assist inserting the cable and navigating feed line 19 around objects that are obstructed by blind spots within housing 23. In embodiments where tube 37 is affixed within housing 23, feed line 19 can be pushed through tube 37, or alternatively, pulled through tube 37 using a pull line, until connector 38 reaches the appropriate communications module 34.

Next, in step 706, a connector 38 of feed line 19 is connected to communications module 34 within housing 23. This can be accomplished through an opening, such as service door 56 shown in FIG. 6, or by any other suitable means. This step can be repeated for each connector 38 attached to each feed line 19 from endcap module 22. Connectors 38 and communications modules 34 can be color coded, or otherwise “keyed” (e.g. by connector type, shape, etc.), to assist matching connector 38 to the appropriate communications module 34.

After feed line 19 is connected to communications module 34, at step 708 endcap module 22 is fastened to housing 23 to secure tube 37 so that tube 37 routes feed line 19 within housing 23 to reduce electromagnetic interference between feed line 19 and electronic components 33 to an acceptable level. The act of fastening endcap module 22 forces endcap module 22 against tube 37 to push tube 37 within housing 23 into the correct routing path. Tube 37 can also be hingedly attached to endcap module 22 so that endcap module 22 can be fastened in a hinged fashion, and also so that tube 37 is properly aligned with endcap module 22 to avoid pinching or crimping feed line 19.

While the exemplary embodiments have been described herein, it is to be understood that the invention is not limited to the disclosed embodiments. The invention is intended to cover various modifications and equivalent arrangements included within the spirit and scope of the appended claims, and scope of the claims is to be accorded an interpretation that encompasses all such modifications and equivalent structures and functions.

1. A device for routing cables within a housing of an electronic device, the device comprising:
a length of tube having a specific shape to route at least one feed line provided therein within the housing of the electronic device, wherein the specific shape includes bends to route the at least one feed line.

2. The device of claim 1, wherein the at least one feed line is an antenna cable and the specific shape routes the antenna cable to provide space between the antenna cable and electronic components to reduce electromagnetic interference between the antenna cable and the electronic components.

3. The device of claim 1, wherein the at least one feed line has a selected minimum bend radius and the bends maintain the at least one feed line above the selected minimum bend radius.

4. The device of claim 3, wherein the at least one feed line is an optical cable.

5. The device of claim 2, wherein the antenna cable connects at least one antenna to at least one communications module of the electronic device.

6. The device of claim 2, wherein the feed line connects at least one scanner device to at least one communications module of the electronic device.

7. The device of claim 2, wherein an end of the length of tube has an attachment mechanism to hingedly attach to an endcap module of the electronic device, the endcap module containing at least one of an antenna and a scanner device.

8. The device of claim 2, wherein the length of tube branches to separately route the antenna cable.

9. The device of claim 2, wherein an end of the length of tube tapers.

10. The device of claim 2, wherein the length of tube has an inner shield to reduce electromagnetic interference.

11. The device of claim 10, wherein the inner shield is any one of a conductive coating and a braid.

12. The device of claim 10, wherein the inner shield is grounded.

13. The device of claim 2, wherein an end of the length of tube is colored to correspond to at least one communications module.

14. An electronic device comprising:
a housing containing electronic components for operation of the electronic device, including at least one communications module;
a module attached to the housing;
a length of tube having a specific shape to route at least one feed line provided therein from the module to the at least one communications module within the housing, wherein the specific shape includes bends to route the feed line to provide space between the feed line and electronic components to reduce electromagnetic interference between the feed line and the electronic components.

15. The electronic device of claim 14, wherein the module is removable.

16. The electronic device of claim 15, wherein an end of the length of tube is hingedly attached to the module.

17. The electronic device of claim 14, wherein the at least one feed line include at least one service loop at an end of the length of tube to allow movement of the tube during assembly.

18. The electronic device of claim 14, wherein an end of the length of tube branches to separately route at least one of the feed lines.

19. The electronic device of claim 14, wherein an end of the length of tube tapers.

20. The electronic device of claim 14, wherein an end of the length of tube is colored to correspond to a connector of the at least one communications module.

21. The electronic device of claim 14, wherein the module is an endcap module.

22. The electronic device of claim 21, wherein the endcap module is attached to any one of the back, front and sides of the housing of the electronic device.

23. A method of assembling a module to an electronic device housing, the method comprising:
inserting a feed line provided within a tube having bends to route the feed line to provide space between the feed line and electronic components within the housing to reduce electromagnetic interference between the feed line and the electronic components, an end of the feed line connected to the module;
attaching a connector from an opposite end of the feed line provided within the tube to a communications module within the housing; and
fastening the module to the housing to secure the tube within the housing to route the feed line within the housing to reduce electromagnetic interference.

24. The method of assembling of claim 23 further comprising hingedly attaching the module to the housing prior to fastening.

25. The method of assembling of claim 24, wherein the tub at the end of the feed line is hingedly attached to the module.

26. The method of assembling of claim 23 further comprising selecting the module in response to a communication requirement.

27. The method of assembly of claim 23, wherein the module is an endcap module.

28. The method of assembly of claim 27, wherein the endcap module is attached to any one of the back, front and sides of the housing of the electronic device.
